(19) United States
(12) Patent Application Publication
(10) Pub. No.: US 2025/0180985 A1
(43) Pub. Date: Jun. 5, 2025

(54) Method of Using and Fabricating a Nanoimprint Template with a Mesa Sidewall Coating

(71) Applicant: CANON KABUSHIKI KAISHA, Tokyo (JP)

(72) Inventors: Teresa Perez Estrada, Pflugerville, TX (US); Mehul N. Patel, Austin, TX (US); Wei Zhang, Austin, TX (US); Zhengmao Ye, Austin, TX (US)

(21) Appl. No.: 18/524,801

(22) Filed: Nov. 30, 2023

(51) Int. Cl. G03F 7/00; B82Y 40/00; G03F 1/38; G03F 7/16; G03F 7/20

(52) U.S. Cl. CPC G03F 7/0002; G03F 1/38; G03F 7/161; G03F 7/2002; G03F 7/2026; B82Y 40/00

(57) ABSTRACT

Method, non-transitory method, and controller for fabricating a template. Including receiving a template with a mesa. The template has a first coating on: the mesa; a recessed surface; and mesa sidewalls connecting the recessed surface to the mesa. A first cured formable material layer has been formed on the first coating on the mesa, the mesa sidewalls, and the recessed surface using a first shaping process. An improvement comprises: forming a second cured formable material layer on top of the first cured formable material layer on the recessed surface using a second shaping process; removing the first cured formable material layer and the first coating on the mesa, and a portion of the second cured formable material layer on the sidewalls and the recessed surface; and removing the first cured formable material layer and the second cured formable material layer from the mesa sidewalls and the recessed surface.

### BACKGROUND OF INVENTION

### Technical Field

The present disclosure relates to photomechanical shaping systems (e.g., Nanoimprint Lithography and Inkjet Adaptive Planarization). In particular, the present disclosure relates to methods of using and fabricating a nanoimprint template with a mesa sidewall coating that is used in photomechanical shaping systems.

### Description of the Related Art

Nano-fabrication includes the fabrication of very small structures that have features on the order of 100 nanometers or smaller. One application in which nano-fabrication has had a sizeable impact is in the fabrication of integrated circuits. The semiconductor processing industry continues to strive for larger production yields while increasing the circuits per unit area formed on a substrate. Improvements in nano-fabrication include providing one or both of greater process control and improving throughput while also allowing continued reduction of the minimum feature dimensions of the structures formed.

One nano-fabrication technique in use today is commonly referred to as nanoimprint lithography. Nanoimprint lithography is useful in a variety of applications including, for example, fabricating one or more layers of integrated devices by shaping a film on a substrate. Examples of an integrated device include but are not limited to CMOS logic, microprocessors, NAND Flash memory, NOR Flash memory, DRAM memory, MRAM, 3D cross-point memory, Re-RAM, Fe-RAM, STT-RAM, MEMS, and the like. Exemplary nanoimprint lithography systems and processes are described in detail in numerous publications, such as U.S. Pat. Nos. 8,349,241, 8,066,930, and 6,936,194, all of which are hereby incorporated by reference herein.

The nanoimprint lithography technique disclosed in each of the aforementioned patents describes the shaping of a film on a substrate by the formation of a relief pattern in a formable material (polymerizable) layer. The shape of this film may then be used to transfer a pattern corresponding to the relief pattern into, onto, or into and onto an underlying substrate.

The shaping process uses a template spaced apart from the substrate. The formable liquid is applied onto the substrate. The template is brought into contact with the formable liquid that may have been deposited as a drop pattern using the formable liquid to spread and fill the space between the template and the substrate. The formable liquid is solidified to form a film that has a shape (pattern) conforming to a shaping surface of the template. After solidification, the template is separated from the solidified layer such that the template and the substrate are spaced apart.

The substrate and the solidified layer may then be subjected to known steps and processes for device (article) fabrication, including, for example, curing, oxidation, layer formation, deposition, doping, planarization, etching, formable material removal, dicing, bonding, and packaging, and the like. For example, the pattern on the solidified layer may be subjected to an etching process that transfers the pattern into the substrate.

### SUMMARY OF THE INVENTION

A first embodiment, may be a method of fabricating a template. The method of fabricating a template can comprise receiving a template with a mesa. The template has a first coating on: the mesa; a recessed surface; and mesa sidewalls connecting the recessed surface to the mesa. A first cured formable material layer has been formed on the first coating on the mesa, the mesa sidewalls, and the recessed surface using a first shaping process. Tn improvement to the method of fabricating the template can comprise: forming a second cured formable material layer on top of the first cured formable material layer on the recessed surface using a second shaping process; removing the first cured formable material layer and the first coating on the mesa, and a portion of the second cured formable material layer on the sidewalls and the recessed surface; and removing the first cured formable material layer and the second cured formable material layer from the mesa sidewalls and the recessed surface.

In an aspect of the first embodiment the second shaping process can include dispensing a plurality of droplets of formable material on the first cured formable material layer on top of the recessed surface.

In an aspect of the first embodiment the second shaping process can include contacting the first cured resist layer on the mesa with a blank template.

In an aspect of the first embodiment, the second shaping process can includes curing the uncured resist to form the second cured resist layer.

In an aspect of the first embodiment, the second shaping process can be performed M times, wherein M is an integer greater than 2.

In an aspect of the first embodiment, N can be 5.

In an aspect of the first embodiment the first shaping process can be different from the second shaping process.

In an aspect of the first embodiment, the first coating can be a 10 nm thick chrome layer deposited using an atomic layer deposition process.

In an aspect of the first embodiment, the mesa can include patterned features underneath the first coating.

In an aspect of the first embodiment removing the first cured formable material layer and the first coating on the mesa, and a portion of the second cured formable material layer on the sidewalls and the recessed surface can include exposing the first cured formable material layer and the chrome on the mesa, and the second cured formable material layer on the sidewalls and the recessed surface to a first etchant for a first etching period.

The first embodiment can further comprise, depositing a plurality of droplets of formable material onto the mesa after the first coating is removed from the mesa; contacting the plurality of droplets of formable material on the mesa with a first patterned template; exposing the plurality of droplets of formable material underneath the template to actinic radiation to form a patterned layer; exposing the patterned layer and the mesa to a second etchant forming patterns in the mesa.

The first embodiment may further comprise depositing a hard mask onto the mesas prior to depositing the droplets of formable material onto the mesa.

The first embodiment may also be a method of shaping a film on a substrate using the template fabricated using the method of the first embodiment, wherein the method of shaping the film further comprises: contacting formable material on the substrate with the template; exposing the formable material under the template to actinic radiation; and separating the template from the formable material.

The first embodiment may also be a method of manufacturing an article, from a substrate on which the film was shaped, further comprising: processing the substrate; and forming the article from the processed substrate.

A second embodiment, may be a non-transitory computer-readable medium encoded with instructions for a template fabrication system. The template fabrication system receiving a template with a mesa, wherein the template has a first coating on: the mesa; a recessed surface; and mesa sidewalls connecting the recessed surface to the mesa. A first cured formable material layer has been formed on the first coating on the mesa, the mesa sidewalls, and the recessed surface using a first shaping process. An improvement to the non-transitory computer-readable medium comprises instructions for: forming a second cured formable material layer on top of the first cured formable material layer on the recessed surface using a second shaping process; removing the first cured formable material layer and the first coating on the mesa, and a portion of the second cured formable material layer on the sidewalls and the recessed surface; and removing the first cured formable material layer and the second cured formable material layer from the mesa sidewalls and the recessed surface.

A third second embodiment, may be a controller of a template replication fabrication system configured to receive a template with a mesa. The template has a first coating on: the mesa; a recessed surface; and mesa sidewalls connecting the recessed surface to the mesa. A first cured formable material layer has been formed on the first coating on the mesa, the mesa sidewalls, and the recessed surface using a first shaping process. An improvement to the controller comprises: the controller sending instructions to the template replication tool for forming a second cured formable material layer on top of the first cured formable material layer on the recessed surface using a second shaping process; the controller sending instructions to an etching tool for removing the first cured formable material layer and the first coating on the mesa, and a portion of the second cured formable material layer on the sidewalls and the recessed surface; and the controller sending instructions to an etching tool for removing the first cured formable material layer and the second cured formable material layer from the mesa sidewalls and the recessed surface.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF THE FIGURES

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention and are therefore not to be considered limiting of its scope, for the invention may admit to other equally effective embodiments.

FIG. 1 is an illustration of an exemplary nanoimprint lithography system having a template with a mesa spaced apart from a substrate as used in an embodiment.

FIGS. 2A-B are illustrations of exemplary templates that may be used in an embodiment.

FIG. 3 is a flowchart illustrating an exemplary imprinting method as used in an embodiment.

FIG. 4 is an illustration of an exemplary nanoimprint lithography system having a template with a mesa spaced apart from a blank template as used in an embodiment.

FIGS. 5A-L are illustrations of a template being used in imprint process.

FIGS. 5M and 5O are micrographs of an imprint field edge of the cured patterned layer.

FIGS. 5N and 5P are micrographs of a mesa and recessed surface of a template.

FIGS. 6A-C are flowcharted illustrating a mesa sidewall coating method used in an embodiment.

FIGS. 7A-H are illustrations of a template being processed using a mesa sidewall coating method as used in an embodiment.

FIGS. 8A-D are illustrations of a template being processed in a portion of a mesa sidewall coating method as used in an embodiment.

Throughout the figures, the same reference numerals and characters, unless otherwise stated, are used to denote like features, elements, components, or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

The nanoimprint lithography technique can use a template with a mesa to shape a formable material with the mesa in a plurality of fields across a substrate. This is done by contacting formable material with the mesa and curing the formable material under the mesa with actinic radiation. The formable material may spread out beyond the mesa during this process forming extrusions. The applicant has found that it is desirable to prevent the extrusions from curing. The applicant has found that an effective way of preventing the extrusions from curing is to coat mesa sidewalls of the template with a material that absorbs the actinic radiation as described in US Patent Publication No. 2023-0095286-A1. The applicant has found that this method is not 100% and small pinholes can form in the coating allowing extrusions to form. What is needed is a method of applying the coating such that pinholes do not form.

### Shaping System

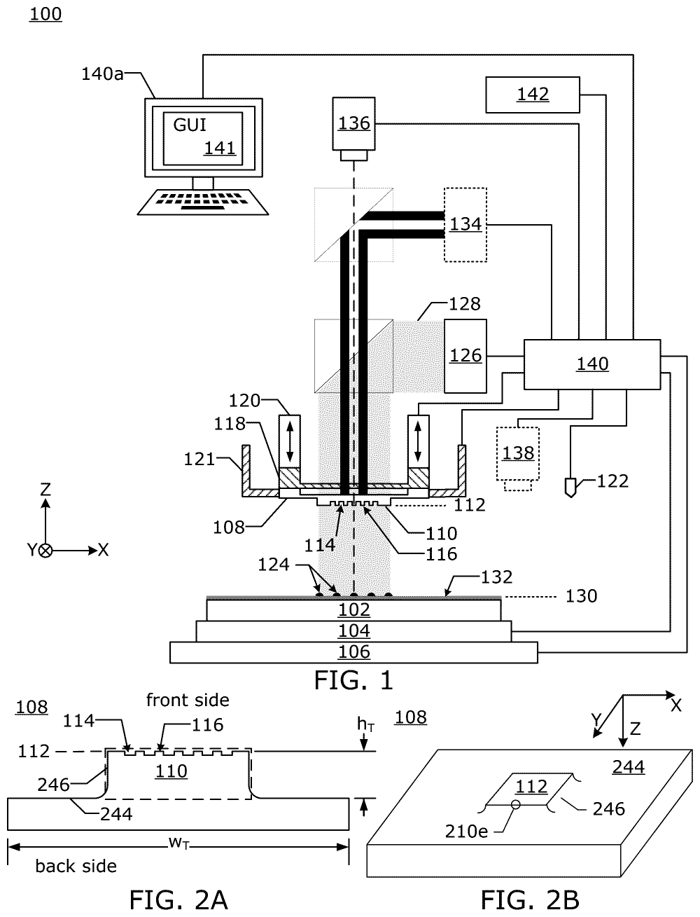

FIG. 1 is an illustration of a shaping system 100 (for example a nanoimprint lithography system or inkjet adaptive planarization system) in which an embodiment may be implemented. The shaping system 100 is used to produce an imprinted (shaped) film on a substrate 102. The substrate 102 may be coupled to a substrate chuck 104. The substrate chuck 104 may be, but is not limited to, one or more of: a vacuum chuck; pin-type chuck; groove-type chuck; electrostatic chuck; electromagnetic chuck; and the like.

The substrate 102 and the substrate chuck 104 may be further supported by a substrate positioning stage 106. The substrate positioning stage 106 may provide translational motion, rotational motion, or both along one or more of the positional axes x, y, and z, and rotational axes θ, ψ, and φ. The substrate positioning stage 106, the substrate 102, and the substrate chuck 104 may also be positioned on a base (not shown). The substrate positioning stage may be a part of a positioning system. In an alternative embodiment, the substrate chuck 104 may be attached to the base.

Spaced-apart from the substrate 102 is a template 108 (also referred to as a superstrate). The template 108 may include a body having a mesa 110 extending towards the substrate 102 on a front side of the template 108. The mesa 110 may have a shaping surface 112 thereon also on the front side of the template 108. The shaping surface 112, also known as a patterning surface, is the surface of the template that shapes the formable material 124. In an embodiment, the shaping surface 112 is planar and is used to planarize the formable material. Alternatively, the template 108 may be formed without the mesa 110, in which case the surface of the template facing the substrate 102 is equivalent to the mesa 110 and the shaping surface 112 is that surface of the template 108 facing the substrate 102, the mesa sidewalls are the sidewalls of the template 108.

The template 108 may be formed from such materials including, but not limited to, one or more of: fused-silica; quartz; silicon; organic polymers; siloxane polymers; borosilicate glass; fluorocarbon polymers; metal; hardened sapphire; and the like. The shaping surface 112 may have features defined by a plurality of spaced-apart template recesses 114 and template protrusions 116. The shaping surface 112 defines a pattern that forms the basis of a pattern to be formed on the substrate 102. In an alternative embodiment, the shaping surface 112 is featureless in which case a planar surface is formed on the substrate. In an alternative embodiment, the shaping surface 112 is featureless and the same size as the substrate and a planar surface is formed across the entire substrate.

Template 108 may be coupled to a template chuck 118. The template chuck 118 may be, but is not limited to one or more of: vacuum chuck; pin-type chuck; groove-type chuck; electrostatic chuck; electromagnetic chuck; and other similar chuck types. The template chuck 118 may be configured to apply one or more of: stress; pressure; and strain to template 108 that varies across the template 108. The template chuck 118 may include a template magnification control system 121. The template magnification control system 121 may include piezoelectric actuators (or other actuators) which can squeeze, stretch, or both squeeze and stretch different portions of the template 108. The template chuck 118 may include a system such as a zone based vacuum chuck, an actuator array, a pressure bladder, etc. which can apply a pressure differential to a back surface of the template causing the template to bend and deform.

The template chuck 118 may be coupled to a shaping head 120 which is a part of the positioning system. The shaping head 120 may be moveably coupled to a bridge. The shaping head 120 may include one or more actuators such as voice coil motors, piezoelectric motors, linear motor, nut and screw motor, etc., which are configured to move the template chuck 118 relative to the substrate in at least the z-axis direction, and potentially other directions (e.g., positional axes x, and y, and rotational axes θ, ψ, and φ).

The shaping system 100 may further comprise a fluid dispenser 122. The fluid dispenser 122 may also be moveably coupled to the bridge. In an embodiment, the fluid dispenser 122 and the shaping head 120 share one or more or all of the positioning components. In an alternative embodiment, the fluid dispenser 122 and the shaping head 120 move independently from each other. The fluid dispenser 122 may be used to deposit liquid formable material 124 (e.g., polymerizable material) onto the substrate 102 in a drop pattern. Additional formable material 124 may also be added to the substrate 102 using one or more techniques, such as, drop dispense, spin-coating, dip coating, chemical vapor deposition (CVD), physical vapor deposition (PVD), thin film deposition, thick film deposition, and the like prior to the formable material 124 being deposited onto the substrate 102. The formable material 124 may be dispensed upon the substrate 102 before, after, or both before and after a desired volume is defined between the shaping surface 112 and the substrate 102 depending on design considerations. The formable material 124 may comprise a mixture including a monomer as described in U.S. Pat. Nos. 7,157,036 and 8,076,386, both of which are herein incorporated by reference.

Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The shaping system 100 may further comprise a curing system that induces a phase change in the liquid formable material into a solid material whose top surface is determined by the shape of the shaping surface 112. The curing system may include at least a radiation source 126 that directs actinic energy along an exposure path 128. The shaping head and the substrate positioning stage 106 may be configured to position the template 108 and the substrate 102 in superimposition with the exposure path 128. The radiation source 126 sends the actinic energy along the exposure path 128 after the template 108 has contacted the formable material 124. FIG. 1 illustrates the exposure path 128 when the template 108 is not in contact with the formable material 124, this is done for illustrative purposes so that the relative position of the individual components can be easily identified. An individual skilled in the art would understand that exposure path 128 would not substantially change when the template 108 is brought into contact with the formable material 124. In an embodiment, the actinic energy may be directed through both the template chuck 118 and the template 108 into the formable material 124 under the template 108. In an embodiment, the actinic energy produced by the radiation source 126 is UV light that induces polymerization of monomers in the formable material 124.

The shaping system 100 may further comprise a field camera 136 that is positioned to view the spread of formable material 124 after the template 108 has contacted the formable material 124. FIG. 1 illustrates an optical axis of the field camera's imaging field as a dashed line. As illustrated in FIG. 1 the shaping system 100 may include one or more optical components (dichroic mirrors, beam combiners, prisms, lenses, mirrors, etc.) which combine the actinic radiation with light to be detected by the field camera. The field camera 136 may be configured to detect the spread of formable material under the template 108. The optical axis of the field camera 136 as illustrated in FIG. 1 is straight but may be bent by one or more optical components. The field camera 136 may include one or more of: a CCD; a sensor array; a line camera; and a photodetector which are configured to gather light that has a wavelength that shows a contrast between regions underneath the template 108 that are in contact with the formable material, and regions underneath the template 108 which are not in contact with the formable material 124. The field camera 136 may be configured to gather monochromatic images of visible light. The field camera 136 may be configured to provide images of the spread of formable material 124 underneath the template 108; the separation of the template 108 from cured formable material; and can be used to keep track of the imprinting (shaping) process. The field camera 136 may also be configured to measure interference fringes, which change as the formable material spreads 124 between the gap between the shaping surface 112 and the substrate surface 130.

The shaping system 100 may further comprise a droplet inspection system 138 that is separate from the field camera 136. The droplet inspection system 138 may include one or more of a CCD, a camera, a line camera, and a photodetector. The droplet inspection system 138 may include one or more optical components such as: lenses, mirrors, optical diaphragms, apertures, filters, prisms, polarizers, windows, adaptive optics, and light sources. The droplet inspection system 138 may be positioned to inspect droplets prior to the shaping surface 112 contacting the formable material 124 on the substrate 102. In an alternative embodiment, the field camera 136 may be configured as a droplet inspection system 138 and used prior to the shaping surface 112 contacting the formable material 124.

The shaping system 100 may further include a thermal radiation source 134 which may be configured to provide a spatial distribution of thermal radiation to one or both of the template 108 and the substrate 102. The thermal radiation source 134 may include one or more sources of thermal electromagnetic radiation that will heat up one or both of the substrate 102 and the template 108 and does not cause the formable material 124 to solidify. The thermal radiation source 134 may include a SLM such as a digital micromirror device (DMD), Liquid Crystal on Silicon (LCoS), Liquid Crystal Device (LCD), etc., to modulate the spatio-temporal distribution of thermal radiation. The shaping system 100 may further comprise one or more optical components which are used to combine the actinic radiation, the thermal radiation, and the radiation gathered by the field camera 136 onto a single optical path that intersects with the imprint field when the template 108 comes into contact with the formable material 124 on the substrate 102. The thermal radiation source 134 may send the thermal radiation along a thermal radiation path (which in FIG. 1 is illustrated as 2 thick dark lines) after the template 108 has contacted the formable material 124. FIG. 1 illustrates the thermal radiation path when the template 108 is not in contact with the formable material 124, this is done for illustrative purposes so that the relative position of the individual components can be easily identified. An individual skilled in the art would understand that the thermal radiation path would not substantially change when the template 108 is brought into contact with the formable material 124. In FIG. 1 the thermal radiation path is shown terminating at the template 108, but it may also terminate at the substrate 102. In an alternative embodiment, the thermal radiation source 134 is underneath the substrate 102, and thermal radiation path is not combined with the actinic radiation and the visible light.

Prior to the formable material 124 being dispensed onto the substrate, a substrate coating 132 may be applied to the substrate 102. In an embodiment, the substrate coating 132 may be an adhesion layer. In an embodiment, the substrate coating 132 may be applied to the substrate 102 prior to the substrate being loaded onto the substrate chuck 104. In an alternative embodiment, the substrate coating 132 may be applied to substrate 102 while the substrate 102 is on the substrate chuck 104. In an embodiment, the substrate coating 132 may be applied by spin coating, dip coating, drop dispense, slot dispense, etc. In an embodiment, the substrate 102 may be a semiconductor wafer. In another embodiment, the substrate 102 may be a blank template (replica blank) that may be used to create a daughter template after being imprinted.

The shaping system 100 may include an imprint field atmosphere control system that includes one or both of a gas system and a vacuum system, an example of which is described in U.S. Patent Publication Nos. 2010/0096764 and 2019/0101823 which are hereby incorporated by reference. The atmosphere control system may include one or more of pumps, valves, solenoids, gas sources, gas tubing, etc. which are configured to cause one or more different gases to flow at different times and different regions. The atmosphere control system may be connected to a first gas transport system that transports gas to and from the edge of the substrate 102 and controls the imprint field atmosphere by controlling the flow of gas at the edge of the substrate 102. The atmosphere control system may be connected to a second gas transport system that transports gas to and from the edge of the template 108 and controls the imprint field atmosphere by controlling the flow of gas at the edge of the template 108. The atmosphere control system may be connected to a third gas transport system that transports gas to and from the top of the template 108 and controls the imprint field atmosphere by controlling the flow of gas through the template 108. One or more of the first, second, and third gas transport systems may be used in combination or separately to control the flow of gas in and around the imprint field.

The shaping system 100 can be regulated, controlled, directed by one or more processors 140 (controller) in communication with one or more components and subsystems such as the substrate chuck 104, the substrate positioning stage 106, the template chuck 118, the shaping head 120, the fluid dispenser 122, the radiation source 126, the thermal radiation source 134, the field camera 136, imprint field atmosphere control system, and the droplet inspection system 138. The processor 140 may operate based on instructions in a computer readable program stored in a non-transitory computer readable memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. The controller 140 may include a plurality of processors that are both included in the shaping system 100a and in communication with the shaping system 100a. The processor 140 may be in communication with a networked computer 140a on which analysis is performed and control files such as a drop pattern are generated. In an embodiment, there are one or more graphical user interface (GUI) 141 on one or both of the networked computer 140a and a display in communication with the processor 140 which are presented to an operator or user.

Either the shaping head 120, the substrate positioning stage 106, or both varies a distance between the mesa 110 and the substrate 102 to define a desired space (a bounded physical extent in three dimensions) that is filled with the formable material 124. For example, the shaping head 120 may apply a force to the template 108 such that mesa 110 is in contact with the formable material 124. After the desired volume is filled with the formable material 124, the radiation source 126 produces actinic radiation (e.g., UV, 248 nm, 280 nm, 350 nm, 365 nm, 395 nm, 400 nm, 405 nm, 435 nm, etc.) causing the formable material 124 to undergo a chemical reaction such as curing, solidifying, cross-linking. The formable material 134 will also conform to a shape of the substrate surface 130 and the shaping surface 112, defining a patterned layer on the substrate 102. The formable material 124 is cured while the template 108 is in contact with formable material 124, forming the patterned layer on the substrate 102. Thus, the shaping system 100 uses a shaping process to form the patterned layer which has recesses and protrusions which are an inverse of the pattern in the shaping surface 112. In an alternative embodiment, the shaping system 100 uses a shaping process to form a planar layer with a featureless shaping surface 112.

The shaping process may be done repeatedly in a plurality of imprint fields (also known as just fields or shots) that are spread across the substrate surface 130. Each of the imprint fields may be the same size as the mesa 110 or just the pattern area of the mesa 110. The pattern area of the mesa 110 is a region of the shaping surface 112 which is used to imprint patterns on a substrate 102 which are features of the device or are then used in subsequent processes to form features of the device. The pattern area of the mesa 110 may or may not include mass velocity variation features (fluid control features) which are used to prevent extrusions from forming on imprint field edges. In an alternative embodiment, the substrate 102 has only one imprint field which is the same size as the substrate 102 or the area of the substrate 102 which is to be patterned with the mesa 110. In an alternative embodiment, the imprint fields overlap. Some of the imprint fields may be partial imprint fields which intersect with a boundary of the substrate 102.

The patterned layer may be formed such that it has a residual layer having a residual layer thickness (RLT) that is a minimum thickness of formable material 124 between the substrate surface 130 and the shaping surface 112 in each imprint field. The patterned layer may also include one or more features such as protrusions which extend above the residual layer having a thickness. These protrusions match the recesses 114 in the mesa 110.

### Template

FIG. 2A is an illustration of a template 108 (not to scale) that may be used in an embodiment. The shaping surface 112 may be on a mesa 110 (identified by the dashed box in FIG. 2A). The mesa 110 is surrounded by a recessed surface 244 on the front side of the template. The mesa 110 has a mesa height h_{T}. The mesa height h_{T} may between 1-200 μm. Mesa sidewalls 246 connect the recessed surface 244 to shaping surface 112 of the mesa 110. The mesa sidewalls 246 surround the mesa 110. In an embodiment in which the mesa is round or has rounded corners, the mesa sidewalls 246 refers to a single mesa sidewall that is a continuous wall without corners. In an embodiment, the mesa sidewalls 246 may have one or more of a perpendicular profile; an angled profile; a curved profile; a staircase profile; a sigmoid profile; a convex profile; or a profile that is combination of those profiles. FIG. 2B is a perspective view of the template 108 (not to scale) showing the mesa edges 210e. FIG. 2B illustrates that the intersection of the mesa sidewalls 246 and the recessed surface 244 may have some curvature due to the process of etching away material from a template precursor to form the mesa 110 on the template 108. The template 108 may have a square planar shape with a template width w_{T} as illustrated in FIGS. 2A-B. In an alternative embodiment, the template width w_{T} is a characteristic width and a planar shape of the template 108 may be a rectangle, parallelogram, polygon, or circle, or some other shape. The template width w_{T} may be between 10-450 mm.

### Shaping Process

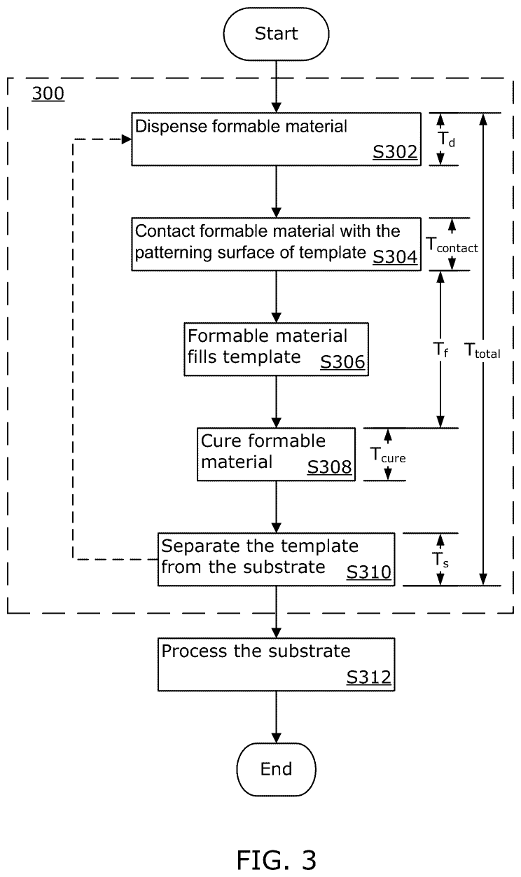

FIG. 3 is a flowchart of a method of manufacturing an article (device) that includes a shaping process 300 performed by the shaping system 100. The shaping process 300 can be used to form patterns in formable material 124 on one or more imprint fields (also referred to as: pattern areas or shot areas). The shaping process 300 may be performed repeatedly on a plurality of substrates 102 by the shaping system 100. The processor 140 may be used to control the shaping process 300.

In an alternative embodiment, the shaping process 300 is used to planarize the substrate 102. In which case, the shaping surface 112 is featureless and may also be the same size or larger than the substrate 102.

The beginning of the shaping process 300 may include a template mounting step causing a template conveyance mechanism to mount a template 108 onto the template chuck 118. The shaping process 300 may also include a substrate mounting step, the processor 140 may cause a substrate conveyance mechanism to mount the substrate 102 onto the substrate chuck 104. The substrate may have one or more coatings and structures. The order in which the template 108 and the substrate 102 are mounted onto the shaping system 100 is not particularly limited, and the template 108 and the substrate 102 may be mounted sequentially or simultaneously.

In a positioning step, the processor 140 may cause one or both of the substrate positioning stage 106 and a dispenser positioning stage to move an imprinting field i (index i may be initially set to 1) of the substrate 102 to a fluid dispense position below the fluid dispenser 122. The substrate 102, may be divided into N imprinting fields, wherein each imprinting field is identified by a shaping field index i. In which N is the number of shaping fields and is a real positive integer such as 1, 10, 62, 75, 84, 100, etc. {N∈ [symbol] ⁺}. In a dispensing step S302, the processor 140 may cause the fluid dispenser 122 to dispense formable material based on a drop pattern onto an imprinting field. In an embodiment, the fluid dispenser 122 dispenses the formable material 124 as a plurality of droplets. The fluid dispenser 122 may include one nozzle or multiple nozzles. The fluid dispenser 122 may eject formable material 124 from the one or more nozzles simultaneously. The imprint field may be moved relative to the fluid dispenser 122 while the fluid dispenser is ejecting formable material 124. Thus, the time at which some of the droplets land on the substrate may vary across the imprint field i. The dispensing step S302 may be performed during a dispensing period T_{d} for each imprint field i.

In an embodiment, during the dispensing step S302, the formable material 124 is dispensed onto the substrate 102 in accordance with a drop pattern. The drop pattern may include information such as one or more of: position to deposit drops of formable material, the volume of the drops of formable material, type of formable material, shape parameters of the drops of formable material, etc. In an embodiment, the drop pattern may include only the volumes of the drops to be dispensed and the location of where to deposit the droplets.

After, the droplets are dispensed, then a contacting step S304 may be initiated, the processor 140 may cause one or both of the substrate positioning stage 106 and a template positioning stage to bring the shaping surface 112 of the template 108 into contact with the formable material 124 in a particular imprint field. The contacting step S304 may be performed during a contacting period T_{contact} which starts after the dispensing period T_{d} and begins with the initial contact of the shaping surface 112 with the formable material 124. In an embodiment, at the beginning of the contact period T_{contact} the template chuck 118 is configured to bow out the template 108 so that only a portion of the shaping surface 112 is in contact with a portion of the formable material. In an embodiment, the contact period T_{contact} ends when the template 108 is no longer bowed out by the template chuck 118. The degree to which the shaping surface 112 is bowed out relative to the substrate surface 130 may be estimated with the spread camera 136. The spread camera 136 may be configured to record interference fringes due to reflectance from at least the shaping surface 112 and the substrate surface 130. The greater the distance between neighboring interference fringes, the larger the degree to which the shaping surface 112 is bowed out.

During a filling step S306, the formable material 124 spreads out towards the edge of the imprint field and the mesa sidewalls 246. The edge of the imprint field may be defined by the mesa sidewalls 246. How the formable material 124 spreads and fills the mesa may be observed via the field camera 136 and may be used to track a progress of a fluid front of formable material. In an embodiment, the filling step S306 occurs during a filling period T_{f}. The filling period T_{f} begins when the contacting step S304 ends. The filling period T_{f} ends with the start of a curing period T_{c}. In an embodiment, during the filling period T_{f} the back pressure and the force applied to the template are held substantially constant. Substantially constant in the present context means that the back pressure variation and the force variation is within the control tolerances of the shaping system 100 which may be less 0.1% of the set point values.

In a curing step S308, the processor 140 may send instructions to the radiation source 126 to send a curing illumination pattern of actinic radiation through the template 108, the mesa 110, and the shaping surface 112 during a curing period T_{c}. The curing illumination pattern provides enough energy to cure (polymerize) the formable material 124 under the shaping surface 112. The curing period T_{c} is a period in which the formable material under the template receives actinic radiation with an intensity that is high enough to solidify (cure) the formable material. In an alternative embodiment, the formable material 124 is exposed to a gelling illumination pattern of actinic radiation before the curing period T_{c} which does not cure the formable material but does increase the viscosity of the formable material.

In a separation step S310, the processor 140 uses one or more of: the substrate chuck 104, the substrate positioning stage 106, template chuck 118, and the shaping head 120 to separate the shaping surface 112 of the template 108 from the cured formable material on the substrate 102 during a separation period Tₛ. If there are additional imprint fields to be imprinted, then the process moves back to step S302. In an alternative embodiment, during step S302 two or more imprint fields receive formable material 124 and the process moves back to steps S302 or S304.

In an embodiment, after the shaping process 300 is finished additional semiconductor manufacturing processing is performed on the substrate 102 in a processing step S312 so as to create an article of manufacture (e.g., semiconductor device). In an embodiment, each imprint field includes a plurality of devices.

The further semiconductor manufacturing processing in processing step S312 may include etching processes to transfer a relief image into the substrate that corresponds to the pattern in the patterned layer or an inverse of that pattern. The further processing in processing step S312 may also include known steps and processes for article fabrication, including, for example, inspection, curing, oxidation, layer formation, deposition, doping, planarization, etching, formable material removal, dicing, bonding, packaging, mounting, circuit board assembly, and the like. The substrate 102 may be processed to produce a plurality of articles (devices).

### Template Replication System

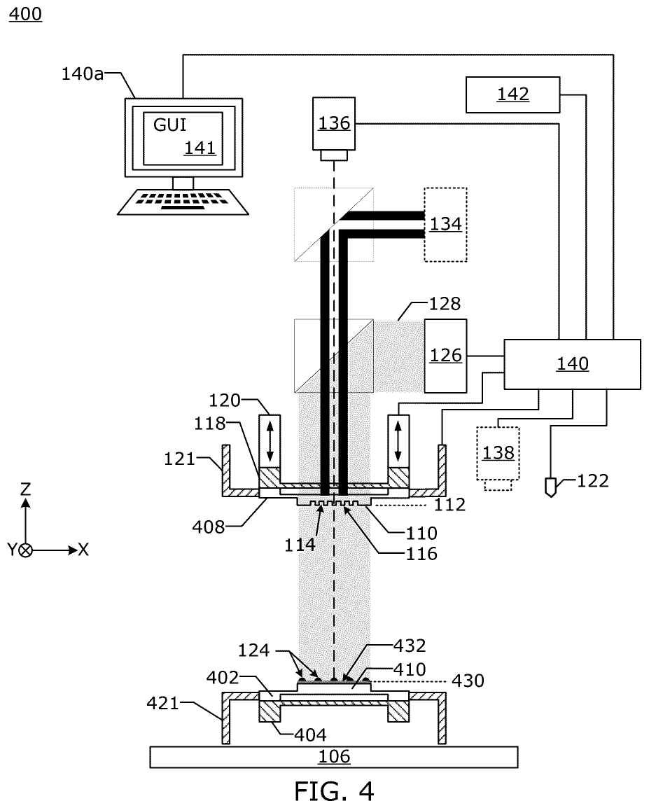

FIG. 4 is an illustration of a template replication system 400 that is an example of the shaping system 100. The template replication system 400 is performed with a master template 408 which includes template recesses 114 and template protrusions 116 but does not necessarily include a mesa 110. The substrate for the template replication system is a blank template 402 with a mesa 410 that is held by a blank template chuck 404 that is substantially the same as the template chuck 118 except that chucking surface of the blank template chuck is facing the chucking surface of the template chuck. The template replication system may include a blank template magnification control system 421 that is substantially the same as the template magnification control system 121. The blank template may include a template coating 432. The template coating may include multiple layers such as a hard mask layer and an adhesion coating. The fluid dispenser 122 may deposit droplets of formable material 124 onto the template coating 432. The template replication system 400 may include a thermal radiation source but only if the master template 408 expands at a different rate than the blank template 402.

The process of template replication uses shaping process 300 but it is done only one time. Steps S312 of the template replication process may include etching, cleaning, inspecting, and forming coating on the mesa sidewalls. In an alternative embodiment, a coating is formed on the mesa sidewalls of the blank template prior to performing the shaping process 300.

### Extrusions

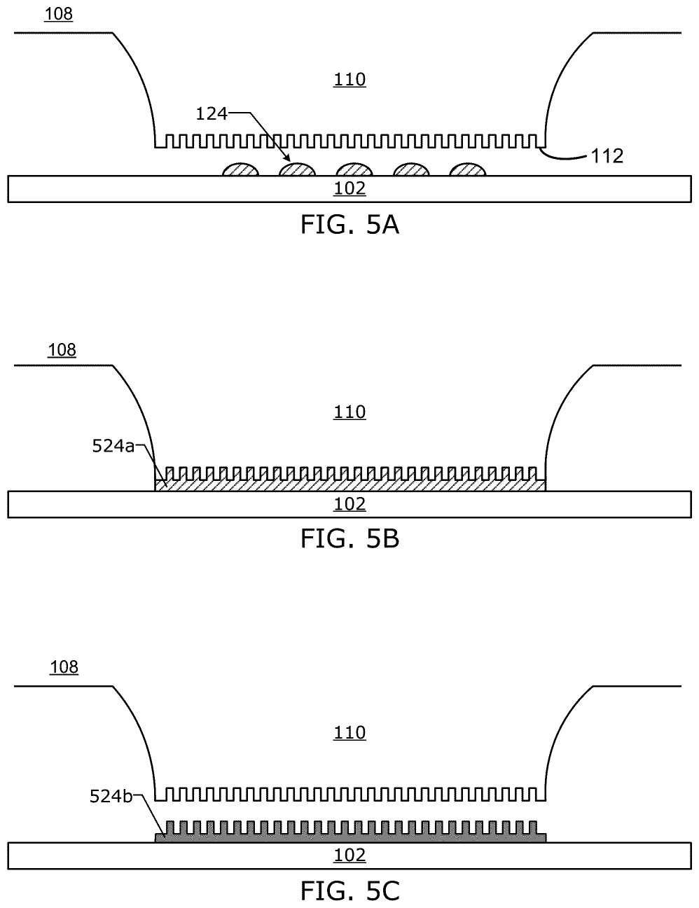

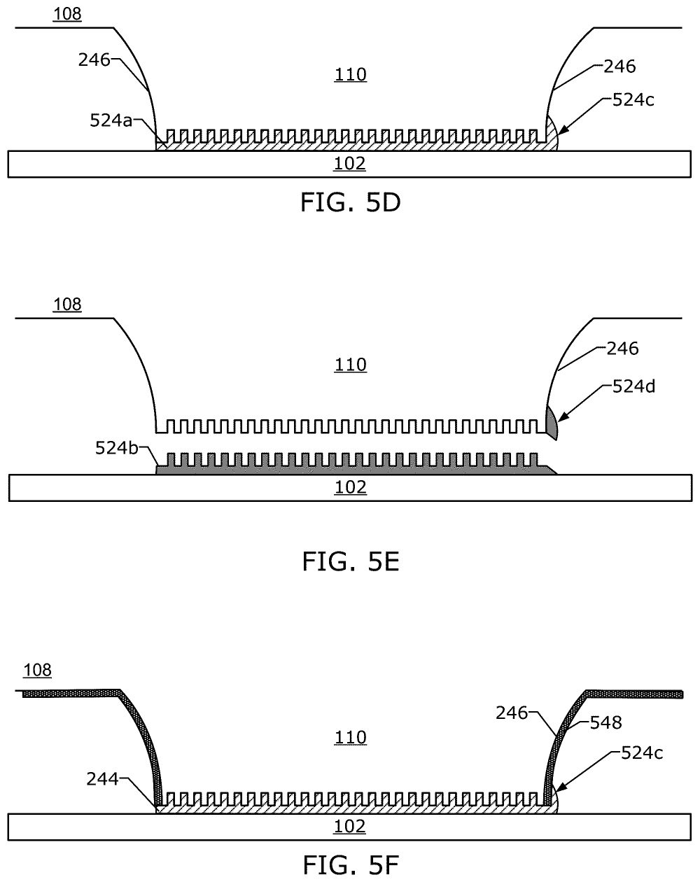

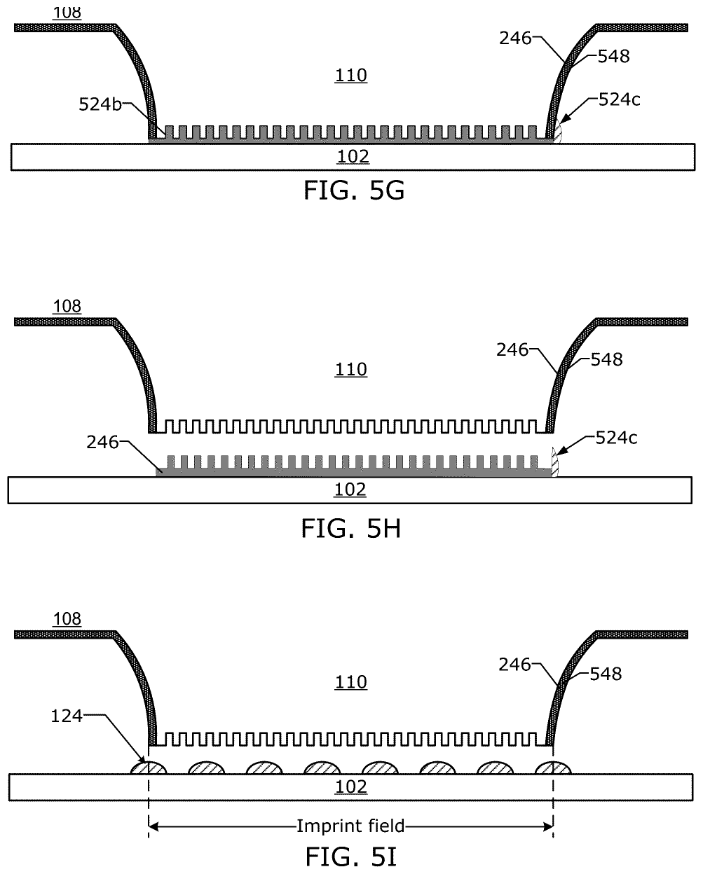

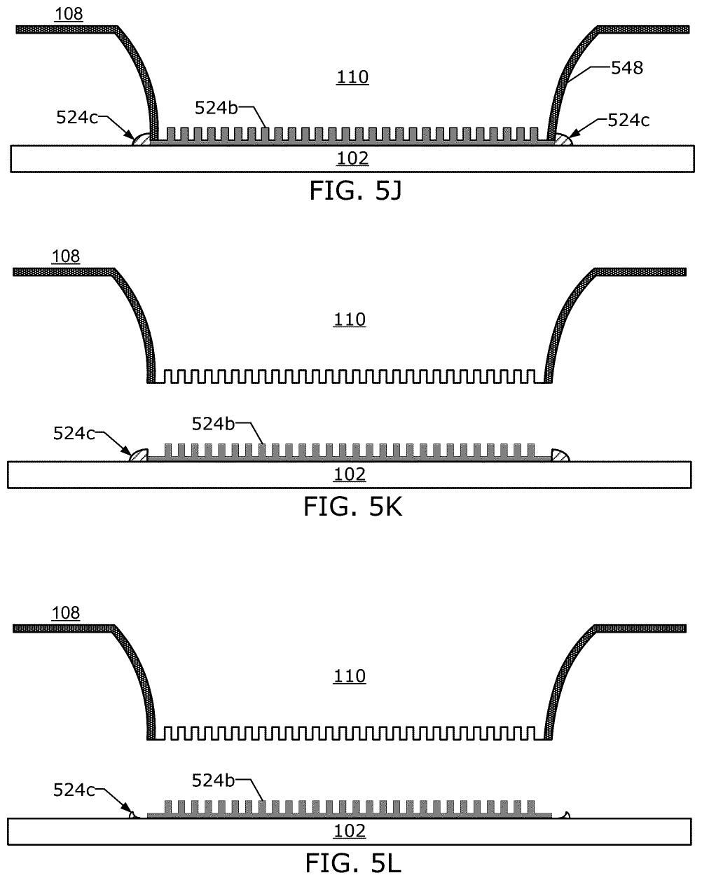

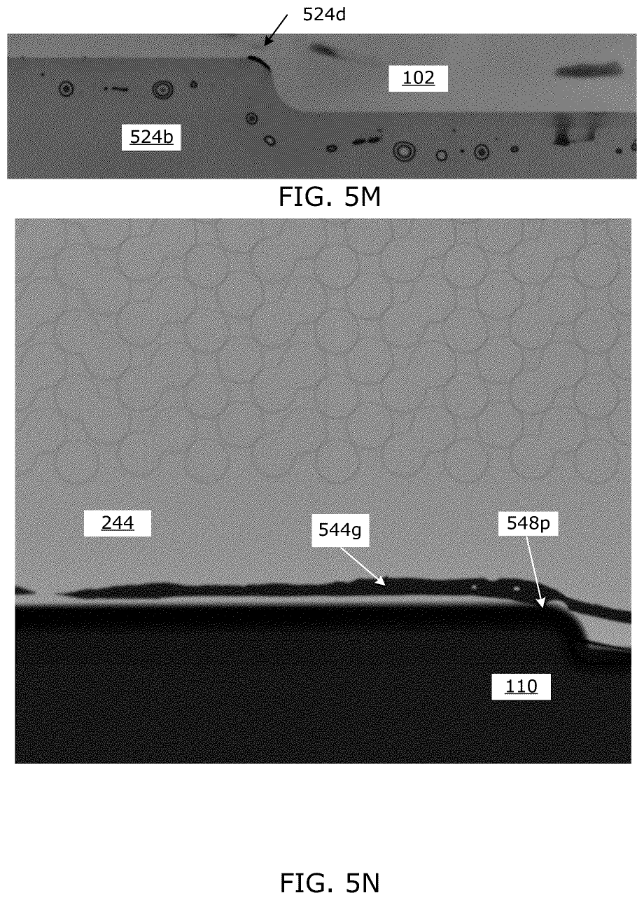

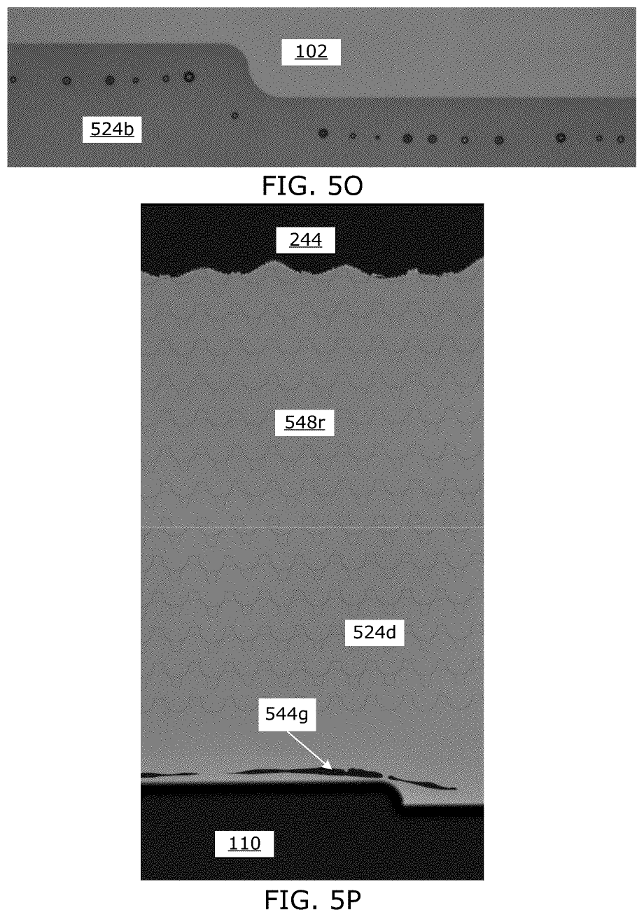

FIGS. 5A-L are illustrations of a template 108 being used in imprint process 300. FIG. 5A is an illustration of a template 108 above the formable material 124 after the dispensing period T_{d} and before the contacting period T_{contact}. FIG. 5B illustrates the template 108 towards the end of the contacting period T_{contact} in which the droplets of formable material merge to form a formable material film 524a that fills the space between the template 108 and the substrate 102. The formable material film 524a is cured to form a cured patterned layer 524b under the template 108. FIG. 5C is an illustration of the template 108 above cured patterned layer 524b after separation period Tₛ.

However, the filling process can cause some formable material 124 to extrude beyond the mesa sidewalls 246 of the mesa 110 forming a liquid extrusion 524c as illustrated in FIG. 5D. When curing the formable material film 524a the liquid extrusions 524c adjacent to the mesa sidewalls 221 are also cured to form a cured extrusion 524d that can stick to the mesa sidewalls 221. Subsequently, as the template 108 separates from the cured patterned layer 524b, the cured extrusions 524d adjacent to the mesa sidewalls 246 can stick to the template 108 and can subsequently contaminate the next process.

The applicant has found that performance of the template 108 is improved when a mesa sidewall coating 548 is applied to the mesa sidewalls 246. The mesa sidewall coating 548 may include one or more of: a metal; a hydrophobic coating; a gas absorption coating; a conductive coating; a hardening coating, an actinic radiation absorbing coating; and an actinic radiation reflecting coating. As illustrated in FIG. 5F the liquid extrusions 524c will still form as illustrated adjacent to the mesa sidewalls 246 of the template 308.

As seen in FIG. 5H as template 108 separates from the cured patterned layer 524b, no formable material remains on the template 108. During the curing step S308 the coating 548 may block actinic radiation from reaching liquid extrusion 524c while the formable material film 244 is turned into the cured patterned layer 246. Any liquid extrusion 524c on the mesa sidewall coating 548 will not be cured but instead can be allowed to evaporate. As the template 108 separates from the cured patterned layer 524b, as seen in FIG. 5H, the cured patterned layer 246 remains on the substrate 102 while the template 308 remains extrusion-free. A liquid extrusion 524c may remain on the substrate 102 or template 108 but will eventually evaporate.

### Mesa Sidewall Coating Testing

The quality of the mesa sidewall coating 548 is very important to the performance of the shaping system 100. The applicant has developed a method of testing the quality of the mesa sidewall coating 548. The testing method includes depositing droplets of formable material 124 on the substrate in the imprint field and on the imprint field edge right below the mesa as illustrated in FIG. 5I. The template 108 will then contact the formable material creating the formable material film 524a along with purposely creating liquid extrusions 524c everywhere along the imprint field edge. The formable material film 524a under the template 108 is cured creating the cured patterned layer 524b and if the mesa sidewall coating 548 is high quality then the liquid extrusion 524c will not be cured but will stay along the imprint field edge as illustrated in FIG. 5J. The template 108 will then separate from the cured patterned layer 524b and the liquid extrusion 524c will tend to stay on the substrate as illustrated in FIG. 5K. Over time, the liquid extrusions 524c will shrink by evaporation as illustrated in FIG. 5L.

The imprinted film will then be inspected for extrusions. FIG. 5M is a micrograph of an imprint field edge of the cured patterned layer 524b obtained with a 20× microscope that were obtained with a mesa sidewall coating 548 fabricated with the prior art process described in US Patent Publication No. 2023-0095286-A1. FIG. 5M shows cured extrusion 524d on the imprint field edge. The applicant has found that these cured extrusions 524d are correlated with small pinholes 548p in the mesa sidewall coating 548 as illustrated in FIG. 5N. FIG. 5N is a micrograph of the recessed surface 244 near the mesa sidewalls 244 of a template produced with a prior art process. The chrome coating does not cover the entire recessed surface. There can be small gaps 544g in the chrome coverage on the recessed surface, this is not an issue unless the small gap 544g is in contact with the mesa sidewall 246, in which case pinholes form. These cured extrusions 524d do not occur all of the time but they do occur often enough to have a small effect on the yield of the final product. FIG. 50 is a micrograph of an imprint field edge of the cured patterned layer 524b obtained with a 20× microscope that were obtained with a mesa sidewall coating 548 fabricated with the applicant's new fabrication process. The dark spots and circles in the cured patterned layer 524b in FIGS. 5M and 5O are artifacts of the method of testing the quality of the mesa sidewall coating 548. Although extrusions can occur, they occur much less frequently with templates fabricated with the applicant's new fabrication process. The applicant has found that when a template is fabricated with a mesa sidewall coating using the new fabrication process the extrusion performance is greatly improved. This extrusion performance is verified by purposely causing extrusions to form and inspecting the films as described above. FIG. 5P is a micrograph of the recessed surface 244 near the mesa sidewalls 244 of a template produced with the current disclosed process. As illustrated in FIG. 5P the mesa sidewall coating also covers a portion 548r of the recessed surface 244. The chrome coating does not cover the entire recessed surface 244. There can be small gaps 544g in the chrome coverage on the recessed surface. The applicant has found that this process does not produce pinholes as the small gaps do not contact the mesa sidewalls.

### Mesa Sidewall Coating Method

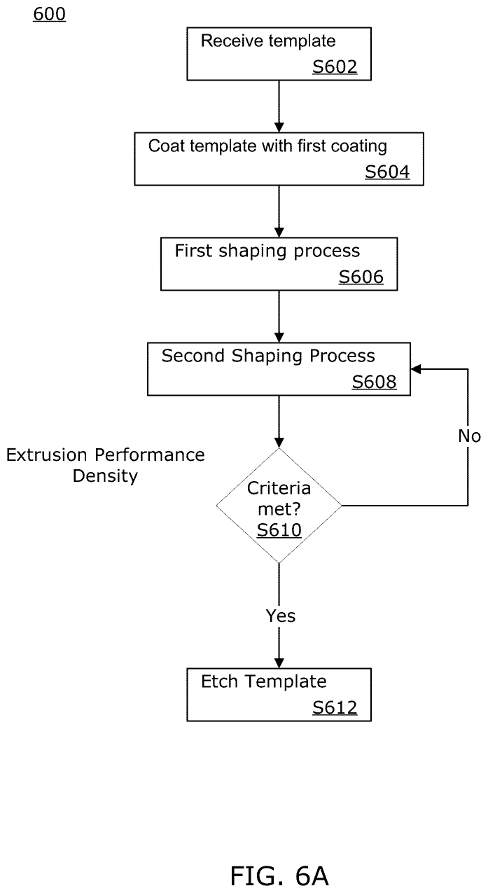

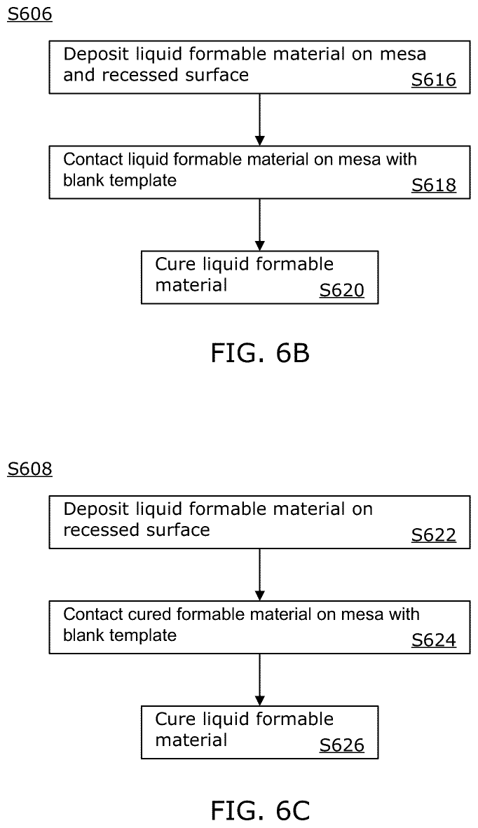

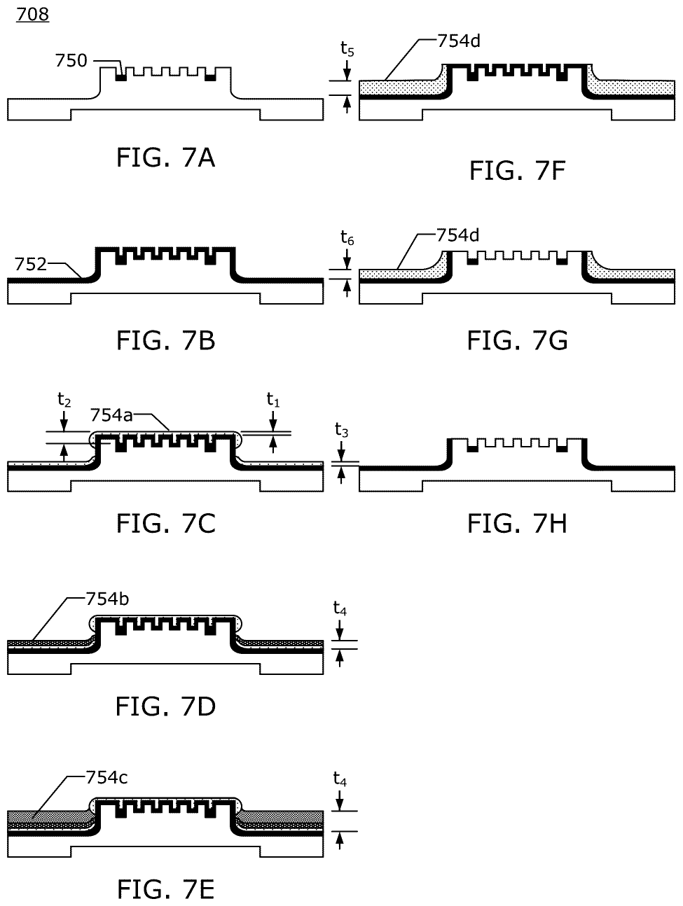

The applicant has developed a new mesa sidewall coating method 600 that improves upon previous methods of coating the mesa sidewalls described by a flowchart in FIG. 6A. The mesa sidewall coating method 600 may include a receiving step S602. The receiving step S602 may include receiving a patterned template 708 as illustrated in FIG. 7A. The patterned template 708 may include alignment marks 750. In an alternative embodiment, the patterned template 708 is an unpatterned template or a featureless glass plate with a mesa 110. The receiving step S602 also includes the processor receiving information about the patterned template 708, such as positions of alignment marks, location of the mesa relative to the alignment marks 750 and the shape of the mesa 110.

The mesa sidewall coating method 600 may include a first coating step S602. The first coating step S604 may include depositing a first coating 752 on: the mesa 110; the mesa sidewalls 246; and the recessed surface 244 as illustrated in FIG. 7B. The first coating 752 may be a light-blocking layer. In one embodiment, the first coating 752 may include one or more of: chromium; molybdenum; tantalum; silicon; tungsten; titanium; aluminum; iron oxide; titanium; and a silver-halide emulsion. The first deposition step 520 may be done using known methods such as atomic layer deposition, sputtering, and evaporation. The first coating 752 may have a thickness of 5-200 nm.

The mesa sidewall coating method 600 may include a first shaping process S606. The details of the first shaping process S606 are described in US Patent Publication No. 2023-0095286-A1 which is hereby incorporated by reference. An intermediate product of the first shaping process is a first cured formable material layer 754a as illustrated in FIGS. 7C-D. The parameters of the first shaping process S606 are adjusted to ensure that there are no non-fill defects on the top of the mesa and the drop density is above a threshold. The parameters of the first shaping process S606 are also adjusted so the that first cured formable material layer 754a will have: a first thickness t₁ of the cured formable material on the mesa 110 above the features of the mesa; a second thickness t₂ of the cured formable material on the mesa 110 including the features of the mesa; cured extrusions of the cured formable material on the mesa sidewalls 246; and a third thickness t₃ of the cured formable material on the recessed surface 244. In an alternative embodiment, there is no cured formable material on the recessed surface 244. In an alternative embodiment, there is cured formable material on only a portion of the recessed surface 244.

The mesa sidewall coating method 600 may include a second shaping process S608. The second shaping process S608 is a process of forming second cured formable material layer 754b on the recessed surface 244 so that the total thickness of cured formable material on the recessed surface 244 has a fourth thickness t₄ as illustrated in FIG. 7D.

The mesa sidewall coating method 600 may include a criteria testing step S610. The criteria testing step S610 is a test that is correlated with the tested or predicted extrusion performance of the template. Extrusion performance means the statistical probability that an extrusion will be formed during the imprinting process over the life of the template. This extrusion performance may be based on experimental testing of templates to obtain images such as those illustrated in FIGS. 5M-N. Examples of the criteria test include the number of times M of the second shaping process S608 is performed. another example of criteria test is the total thickness of cured formable material on the recessed surface 244. If the template does not pass the criteria testing step S610, then the mesa sidewall coating method 600 moves back to the second shaping process S608 and an additional cured formable material layer 754c is formed on the template as illustrated in FIG. 7E. If the template does pass the criteria testing step S610, then the mesa sidewall coating method 600 moves to an etching step S612. The number of times M may be 1, 2, 5, 8, 10, 12, or 15 times or however many times is necessary to prevent extrusions being formed. The number of times M may be adjusted based on other criteria such as extrusion performance or the total thickness of cured formable material on the recessed surface 244.

The mesa sidewall coating method 600 may include an etching step S612. The etching step S612 includes a plurality of etching substeps. A first etching substep may include removing cured formable material from the mesa as illustrated in FIG. 7F. The first etching substep may be an isotropic etching process or anisotropic etching process. The first etching substep may include exposing the cured formable material to one or more of a liquid, a gas, and a plasma for a period of time such that chrome on the mesa is exposed. The first etching substep may be performed for a fixed period of time or until all of the chrome on the mesa is exposed. A side effect of the first etching substep is that the total cured formable material 754d on the recessed surface will have a new fifth thickness t₅ that is less than the fourth thickness t₄ because cured formable material on the recessed surface is etched at same time that the cured formable material is etched on the template as illustrated in FIG. 7F. In an embodiment, the fifth thickness t₅ is correlated with the fourth thickness t₄ and the second thickness t₂. In an exemplary embodiment the fifth thickness t₅ is approximately equal to the fourth thickness t₄ minus the second thickness t₂ (t₅≈t₄−t₂).

The etching step S612 includes a second etching substep. The second etching substep may be an isotropic etching process or an anisotropic etching process. The second etching substep may include exposing the first coating 752 to one or more of a liquid, a gas, and a plasma for a period of time such that the patterned features under the chrome on the mesa and the alignment marks are exposed. The second etching substep has an etching differential between the first coating 752, the material of the mesa, and the total cured formable material 754d on the recessed surface 244 and the mesa sidewalls 246. The second etching substep may also have an etching differential between the alignment marks 750 and the first coating 752. The alignment marks 750 may have a protective coating or may be made of a different material from the first coating 752. After the second etching substep the first coating 752 is removed from the mesa and the total cured formable material 754d has a sixth thickness t₆ that is less than a fifth thickness t₅ as illustrated in FIG. 7G. Removing the first coating 752 also removes some of the total cured formable material 754d and the total cured formable material 754d has new sixth thickness t₆. The fourth thickness t₄ is selected such that there is still sufficient formable material on mesa sidewalls to protect the first coating on the mesa sidewalls.

The etching step S612 includes a third etching substep which may be a descumming step. The third etching substep includes removing substantially all of the remaining formable material leaving a template that has a first coating on the mesa sidewall without pinholes or other openings close to the mesa sidewalls. The patterned template 708 includes features that have a maximum depth d. The maximum depth may be between 1-250 nm. In a first embodiment, the mesa may be surrounded by a step that has with a maximum depth d surrounding the mesa. In a second embodiment, the first coating does not extend to the top of the mesa, but extends close to the maximum depth d from the top of the mesa.

### First Shaping Process

The first shaping process S606 is summarized in FIG. 6B. The first shaping process S606 can include a first dispensing step S616. The first dispensing step S616 includes dispensing drops of formable material 124 onto the mesa 110 and the recessed surface 244 of the template 108. The drops of formable material 124 are dispensed in a drop pattern so the that first cured formable material layer 754a will have: a first thickness t₁ of the cured formable material on the mesa 110 above the features of the mesa; a second thickness t₂ of the cured formable material on the mesa 110 including the features of the mesa; no non-fill defects on the top of the mesa; cured extrusions of the cured formable material on the mesa sidewalls 246; and a third thickness t₃ of the cured formable material on the recessed surface 244. In an alternative embodiment, drops of formable material 124 are not dispensed onto the recessed surface 244 or are dispensed only on a portion of the recessed surface 244.

The first shaping process S606 can include a first contacting step S618. The first contacting step S618 can include contacting liquid formable material 124 on the mesa with a blank template. The first contacting step S618 is performed such that the formable material spreads and fills the features on the mesa and forms extrusions on the mesa sidewall.

The first shaping process S606 can include a first curing step S620. The first curing step S620 can include exposing the formable material 124 to curing energy. The curing energy may be actinic radiation, thermal energy, or chemical energy, or some other method of curing, solidifying, cross-linking, the formable material to form the first cured formable material layer 754a. In an embodiment, the first cured formable material layer 754a includes: material on the mesa 110, extrusions on the mesa sidewalls 266, and material on the recessed surface 244. In an embodiment, the first cured formable material layer 754a includes: material on the mesa 110, extrusions on the mesa sidewalls 266, and material on some of the recessed surface 244. In an embodiment, the first cured formable material layer 754a includes: material on the mesa 110 and extrusions on the mesa sidewalls 266. In an embodiment, the first cured formable material layer 754a includes material on the mesa 110.

### Second Shaping Process

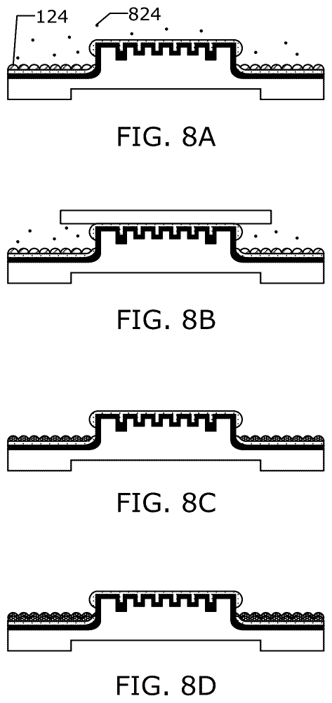

The second shaping process S608 is summarized in FIG. 6C. The second shaping process S608 can include a second dispensing step S622. The second dispensing step S616 includes dispensing drops of formable material 124 onto the recessed surface 244 of the template 108 as illustrate in FIG. 8A. The drops of formable material are dispensed in a dispensed drop pattern so as to form a thick layer of formable material 124. The drops of formable material may be on top of a first cured formable material layer 754a. When forming a thick layer of formable material 124 a formable material vapor 824 also forms above the template. This formable material vapor 824 can introduce unintended variations in the thickness of the formable material on the mesa 110.

The second shaping process S608 can include a second contacting step S624. The second contacting step S618 can include contacting first cured formable material layer 754a on the mesa with a blank template as illustrated in FIG. 8B. The second contacting step S624 is performed such that formable material vapor that is above the mesa is trapped between the blank template and the formable material layer 754a and spreads out forming a substantially uniform layer.

The second shaping process S608 can include a second curing step S620. The second curing step S620 can include exposing the formable material 124 to curing energy. The curing energy may be actinic radiation, thermal energy, or chemical energy, or some other method of curing, solidifying, cross-linking, the formable material to form the second cured formable material layer 754b as illustrated in FIG. 8C. The second shaping process S608 can be repeated producing additional cured formable material on the recessed surface as illustrated in FIG. 8D.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A method of fabricating a template, comprising receiving a template with a mesa, wherein the template has a first coating on: the mesa; a recessed surface; and mesa sidewalls connecting the recessed surface to the mesa, wherein a first cured formable material layer has been formed on the first coating on the mesa, the mesa sidewalls, and the recessed surface using a first shaping process, wherein an improvement to the method of fabricating the template comprises:
forming a second cured formable material layer on top of the first cured formable material layer on the recessed surface using a second shaping process;
removing the first cured formable material layer and the first coating on the mesa, and a portion of the second cured formable material layer on the sidewalls and the recessed surface; and
removing the first cured formable material layer and the second cured formable material layer from the mesa sidewalls and the recessed surface.

2. The method of claim 1, wherein the second shaping process includes:
dispensing a plurality of droplets of formable material on the first cured formable material layer on top of the recessed surface.

3. The method of claim 2, wherein the second shaping process includes:
contacting the first cured resist layer on the mesa with a blank template.

4. The method of claim 3, wherein the second shaping process includes:
curing the uncured resist to form the second cured resist layer.

5. The method of claim 1, wherein the second shaping process is performed M times, wherein M is an integer greater than 2.

6. The method of claim 5, wherein M is 5.

7. The method of claim 1, wherein the first shaping process is different from the second shaping process.

8. The method of claim 1, wherein the first coating is a 10 nm thick chrome layer deposited using an atomic layer deposition process.

9. The method of claim 1, wherein the mesa includes patterned features underneath the first coating.

10. The method of claim 1, wherein removing the first cured formable material layer and the first coating on the mesa, and a portion of the second cured formable material layer on the sidewalls and the recessed surface includes exposing the first cured formable material layer and the chrome on the mesa, and the second cured formable material layer on the sidewalls and the recessed surface to a first etchant for a first etching period.

11. The method of claim 1, further comprising:
depositing a plurality of droplets of formable material onto the mesa after the first coating is removed from the mesa;
contacting the plurality of droplets of formable material on the mesa with a first patterned template;
exposing the plurality of droplets of formable material underneath the template to actinic radiation to form a patterned layer; and
exposing the patterned layer and the mesa to a second etchant forming patterns in the mesa.

12. The method of claim 1, further comprising depositing a hard mask onto the mesas prior to depositing the droplets of formable material onto the mesa.

13. A method of shaping a film on a substrate using the template fabricated using the method of claim 1, wherein the method of shaping the film further comprises:
contacting formable material on the substrate with the template;
exposing the formable material under the template to actinic radiation; and
separating the template from the formable material.

14. A method of manufacturing an article, from a substrate on which the film was shaped according to the method of claim 13, further comprising:
processing the substrate; and
forming the article from the processed substrate.

15. A non-transitory computer-readable medium encoded with instructions for a template fabrication system, wherein the template fabrication system receives a template with a mesa, wherein the template has a first coating on: the mesa; a recessed surface; and mesa sidewalls connecting the recessed surface to the mesa, wherein a first cured formable material layer has been formed on the first coating on the mesa, the mesa sidewalls, and the recessed surface using a first shaping process, wherein an improvement to the non-transitory computer-readable medium comprises instructions for:
forming a second cured formable material layer on top of the first cured formable material layer on the recessed surface using a second shaping process;
removing the first cured formable material layer and the first coating on the mesa, and a portion of the second cured formable material layer on the sidewalls and the recessed surface; and
removing the first cured formable material layer and the second cured formable material layer from the mesa sidewalls and the recessed surface.

16. A controller of a template fabrication system configured to receive a template with a mesa, wherein the template has a first coating on: the mesa; a recessed surface; and mesa sidewalls connecting the recessed surface to the mesa, wherein a first cured formable material layer has been formed on the first coating on the mesa, the mesa sidewalls, and the recessed surface using a first shaping process, wherein an improvement to the controller comprises:
the controller sending instructions to the template replication tool for forming a second cured formable material layer on top of the first cured formable material layer on the recessed surface using a second shaping process;
the controller sending instructions to an etching tool for removing the first cured formable material layer and the first coating on the mesa, and a portion of the second cured formable material layer on the sidewalls and the recessed surface; and
the controller sending instructions to an etching tool for removing the first cured formable material layer and the second cured formable material layer from the mesa sidewalls and the recessed surface.
